(19) United States
(12) Patent Application Publication
(10) Pub. No.: US 2023/0168556 A1
(43) Pub. Date: Jun. 1, 2023

(54) ARRAY SUBSTRATE AND DISPLAY PANEL

(71) Applicant: Shenzhen China Star Optoelectronics Semiconductor Display Technology Co., Ltd., Shenzhen, Guangdong (CN)

(72) Inventors: Xuebin YAO, Shenzhen, Guangdong (CN); Bangyin PENG, Shenzhen, Guangdong (CN); Ilgon KIM, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/963,255

(22) PCT Filed: Jul. 9, 2020
(86) PCT No.: PCT/CN2020/101079

§ 371 Date: Jul. 20, 2020

(30) Foreign Application Priority Data
Jun. 10, 2020 (CN) 202010523474.X

(51) Int. Cl. G02F 1/1368; H01L 27/12; H01L 29/786; G02F 1/1333

(52) U.S. Cl. CPC G02F 1/1368; G02F 1/133345; H01L 27/1244; H01L 29/78669; G02F 2202/103

(57) ABSTRACT

The present application provides an array substrate and a display panel. The array substrate includes a substrate and a thin film transistor layer. The thin film transistor layer includes a first metal layer and a second metal layer, the first metal layer includes at least one first metal trace, the second metal layer includes at least one second metal trace, the thin film transistor layer includes a trace crossover area, a barrier layer is disposed between the first metal layer and the second metal layer, and the barrier layer at least covers the trace crossover area.

### FIELD OF INVENTION

The present application relates to a field of display technology, and more particularly to an array substrate and a display panel.

### BACKGROUND

With development of display technology, in display panels with high refresh rates and high resolutions such as frequencies of 120 Hz and 8K pixels, as a resolution of a display panel increases, a refresh frequency becomes higher, which makes charging loads of the display panel heavier.

### Technical Problem

At present, in order to ensure a charging rate of the display panel, a method of increasing a thickness of metal traces is adopted. However, due to the increased thickness of the metal traces, this results in an increased climbing slope of the metal traces and a topography of the metal traces in different layers such as M1 and M2 where they interlace and cross each other (metal cross position), and risks of short-circuiting of the metal traces of different layers at the location of the intersecting cross-line are increased. Especially, in display panels of high refresh rate and high-resolution, since a number of pixel units is increased and a number of positions where metal traces of different layers intersect and cross each other is also increased, risks of short circuits at positions where metal traces of different layers intersect and cross each other are further increased.

### Technical Solution

The present application provides an array substrate and a display panel to solve the technical problems that short-circuits easily happened at the positions where metal traces of different layers interlace and cross in a display panel with high refresh rate and high resolution.

In order to solve the above problems, the technical solutions provided by this application are as follows:

The present application provides an array substrate, comprising a substrate and a thin film transistor layer disposed on the substrate, wherein:

the thin film transistor layer comprises a first metal layer and a second metal layer disposed above the first metal layer, and the first metal layer comprises at least one first metal trace, and the second metal layer comprises at least one second metal trace, and the thin film transistor layer comprises a trace crossover area, and a projection of the first metal trace on the substrate overlaps a projection of the second metal trace on the substrate in the trace crossover area; and

a barrier layer is disposed between the first metal layer and the second metal layer, and the barrier layer at least covers the trace crossover area.

In the array substrate of the present application, the first metal layer further comprises a gate, and the thin film transistor layer further comprises an active layer disposed over the gate, and the second metal layer further comprise source/drain electrodes connected to both ends of the active layer, and the material of the active layer is the same as the material of the barrier layer, and the active layer and the barrier layer are an integrally formed structure.

In the array substrate of the present application, an insulating layer covering the first metal layer is disposed between the first metal layer and the second metal layer, and the barrier layer is provided on the insulating layer at a side close to the second metal layer.

In the array substrate of the present application, thicknesses of the active layer and the barrier layer are the same.

In the array substrate of the present application, materials of the active layer and the barrier layer are both amorphous silicon.

In the array substrate of the present application, the first metal layer comprises a plurality of the first metal traces, and the second metal layer comprises a plurality of the second metal traces, and the trace crossover area comprises a plurality of crossover sub-areas, and projections of the plurality of first metal traces on the substrate overlap projections of the plurality of second metal traces on the substrate in each of the trace crossover sub-areas; and

the barrier layer comprises a plurality of barrier sub-layers corresponding to the plurality of trace crossover sub-areas, respectively, and the barrier sub-layer covers at least the corresponding trace crossover sub-areas.

In the array substrate of the present application, among the plurality of barrier sub-layers, adjacent barrier sub-layers are integrally connected.

In the array substrate of the present application, a part of the barrier sub-layers that are integrated connected is disposed along an extending direction of one of the first metal traces or along an extending direction of one of the second metal traces.

In the array substrate of the present application, a width of the barrier layer at the trace crossover area is greater than a width of the first metal trace at the trace crossover area.

In the array substrate of the present application, a width of the barrier layer at the trace crossover area is greater than a width of the second metal trace at the trace crossover area.

The present application further provides a display panel comprising a color filter substrate and the array substrate according to the previous embodiment, wherein a liquid crystal layer is disposed between the color filter substrate and the array substrate.

In the display panel of the present application, the first metal layer further comprises a gate, and the thin film transistor layer further comprises an active layer disposed over the gate, and the second metal layer further comprise source/drain electrodes connected to both ends of the active layer, and the material of the active layer is the same as the material of the barrier layer, and the active layer and the barrier layer are an integrally formed structure.

In the display panel of the present application, an insulating layer covering the first metal layer is disposed between the first metal layer and the second metal layer, and the barrier layer is provided on the insulating layer at a side close to the second metal layer.

In the display panel of the present application, thicknesses of the active layer and the barrier layer are the same.

In the display panel of the present application, materials of the active layer and the barrier layer are both amorphous silicon.

In the display panel of the present application, the first metal layer comprises a plurality of the first metal traces, and the second metal layer comprises a plurality of the second metal traces, and the trace crossover area comprises a plurality of crossover sub-areas, and projections of the plurality of first metal traces on the substrate overlap projections of the plurality of second metal traces on the substrate in each of the trace crossover sub-areas; and

the barrier layer comprises a plurality of barrier sub-layers corresponding to the plurality of trace crossover sub-areas, respectively, and the barrier sub-layer covers at least the corresponding trace crossover sub-areas.

In the display panel of the present application, among the plurality of barrier sub-layers, adjacent barrier sub-layers are integrally connected.

In the display panel of the present application, a part of the barrier sub-layers that are integrated connected is disposed along an extending direction of one of the first metal traces or along an extending direction of one of the second metal traces.

In the display panel of the present application, a width of the barrier layer at the trace crossover area is greater than a width of the first metal trace at the trace crossover area.

In the display panel of the present application, a width of the barrier layer at the trace crossover area is greater than a width of the second metal trace at the trace crossover area.

### Advantageous Effects

Advantageous effects of the present application are: a barrier layer in the present application is provided between a first metal layer and a second metal layer, and the barrier layer covers at least a trace crossover area, thereby preventing a first metal trace from being short-circuited with a second metal trace at the trace crossover area, thereby improving stability of the first metal trace and the second metal trace at the crossover area.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a first schematic structural diagram of an array substrate in an embodiment of the present application.

FIG. 2 is a schematic diagram of a cross-sectional layered structure at A-A in FIG. 1.

FIG. 3 is a second schematic structural diagram of an array substrate in an embodiment of the present application.

FIG. 4 is a schematic diagram of a cross-sectional layered structure at B-B in FIG. 3.

FIG. 5 is a schematic structural diagram of a display panel in an embodiment of the present application.

### DETAILED DESCRIPTION

The technical solutions in the embodiments of the present application will be described clearly and completely with reference to the drawings in the embodiments of the present application.

In the description of this application, it should be understood that the terms “vertical”, “horizontal”, “length”, “width”, “upper”, “lower”, “front”, “rear”, “left”, “right”, etc. indicated orientation or positional relationship is based on the orientation or positional relationship shown in the drawings, only to facilitate the description of this application and simplify the description, not to indicate or imply the device referred to Or the element must have a specific orientation, be constructed and operated in a specific orientation, and therefore cannot be understood as a limitation of the present application. In addition, the terms “first” and “second” are used for descriptive purposes only, and cannot be understood as indicating or implying relative importance or implicitly indicating the number of technical features indicated. Thus, the features defined as “first” and “second” may explicitly or implicitly include one or more of the features. In the description of this application, the meaning of “a plurality of” is two or more, unless otherwise specifically limited.

In the description of this application, it should be noted that, unless otherwise clearly specified and limited, the terms “installation”, “connection”, and “connection” should be understood in a broad sense, for example, it can be fixed connection or detachable Connected, or integrally connected; it can be mechanical, electrical, or can communicate with each other; it can be directly connected, or it can be indirectly connected through an intermediary, it can be the connection between two elements or the interaction of two elements relationship. Those of ordinary skill in the art can understand the specific meanings of the above terms in this application according to specific situations.

In this application, unless otherwise clearly specified and defined, the first feature “above” or “below” the second feature may include the direct contact of the first and second features, or may include the first and second features Not direct contact but contact through another feature between them. Moreover, the first feature is “above”, “above” and “above” the second feature includes that the first feature is directly above and obliquely above the second feature, or simply means that the first feature is higher in level than the second feature. The first feature is “below”, “below”, and “below” the second feature includes that the first feature is directly below and obliquely below the second feature, or simply means that the first feature is less horizontal than the second feature.

The following disclosure provides many different embodiments or examples for implementing different structures of the present application. In order to simplify the disclosure of the present application, the components and settings of specific examples are described below. Of course, they are only examples, and the purpose is not to limit this application. In addition, the present application may repeat reference numerals and/or reference letters in different examples. Such repetition is for the purpose of simplicity and clarity, and does not itself indicate the relationship between the various embodiments and/or settings discussed. In addition, the present application provides examples of various specific processes and materials, but those of ordinary skill in the art may be aware of the application of other processes and/or the use of other materials.

Technical solutions of the present application will now be described in combination with specific embodiments.

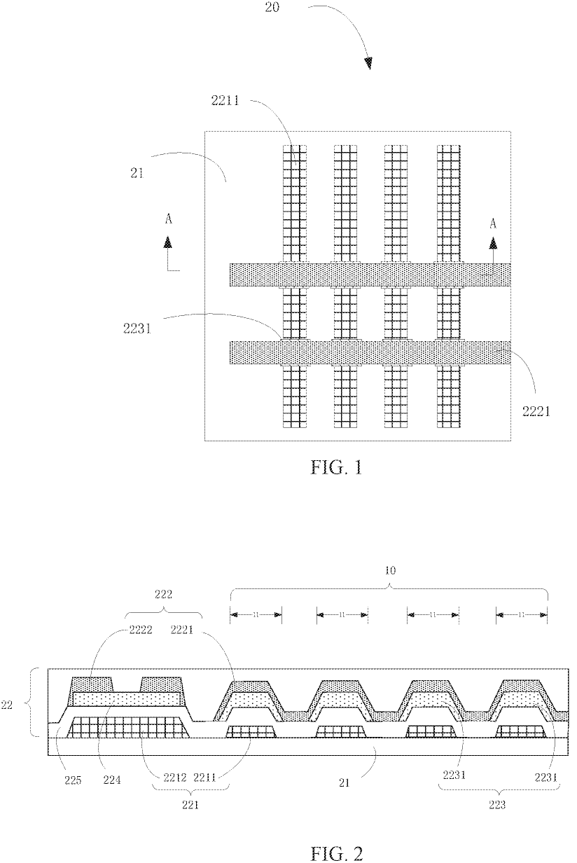

The present application provides an array substrate 20, as shown in FIGS. 1 to 4, comprising a substrate 21 and a thin film transistor layer 22 disposed on the substrate 21.

The thin film transistor layer 22 comprises a first metal layer 221 and a second metal layer 222 disposed over the first metal layer 221. The first metal layer 221 comprises at least one first metal trace 2211, and the second metal layer 222 comprises at least one second metal trace 2221. The thin film transistor layer 22 comprises a trace crossover area 10, and a projection of the first metal trace 2211 on the substrate 21 overlaps a projection of the second metal trace 2221 on the substrate 21 in the trace crossover area 10.

A barrier layer 223 is disposed between the first metal layer 221 and the second metal layer 222, and the barrier layer 223 at least covers the trace crossover area 10.

It can be understood that in display panels with high refresh rates and high resolutions such as frequencies of 120 Hz and 8K pixels, as a resolution of a display panel increases, a refresh frequency becomes higher, which makes charging loads of the display panel heavier. At present, in order to ensure a charging rate of the display panel, a method of increasing a thickness of metal traces is adopted. However, due to the increased thickness of the metal traces, this results in an increased climbing slope of the metal traces and a topography of the metal traces in different layers such as M1 and M2 where they interlace and cross each other (metal cross position), and risks of short-circuiting of the metal traces of different layers at the location of the intersecting cross-line are increased. Especially, in display panels of high refresh rate and high-resolution, since a number of pixel units is increased and a number of positions where metal traces of different layers intersect and cross each other is also increased, risks of short circuits at positions where metal traces of different layers intersect and cross each other are further increased. In the present application, the barrier layer 223 is disposed between the first metal layer 221 and the second metal layer 222, and the barrier layer 223 covers at least the trace crossover area 10, thereby preventing the first metal trace 2211 from being short-circuited with the second metal trace 2221 at the trace crossover area 10, and improving stability of the first metal trace 2211 and the second metal trace 2221 at the trace crossover area 10.

As mentioned above, in this embodiment, the first metal trace 2211 and the second metal trace 2221 may be multiple traces located at different levels in the array substrate 20 and interleaved with each other. Specifically, the first metal trace 2211 may be a scan line, and the second metal trace 2221 may be a data line. In addition, the barrier layer 223 may be a variety of materials with an insulating effect, which is not limited herein.

In one embodiment, as shown in FIG. 2 and FIG. 4, the first metal layer 221 further comprises a gate 2212, and the thin film transistor layer 22 further comprises an active layer 224 disposed over the gate 2212. The second metal layer 222 further comprises source/drain electrodes 2222 connected to both ends of the active layer 224, respectively. The material of the active layer 224 is the same as the material of the barrier layer 223, and the active layer 224 and the barrier layer 223 are an integrally formed structure. It can be understood that the material of the active layer 224 is the same as the material of the barrier layer 223, which is convenient for the barrier layer 223 and the active layer 224 to be formed by the same manufacturing process, so that the active layer 224 and the barrier layer 223 are formed into an integral structure. Compared with an existing array substrate 20, there is no additional manufacturing process added. Specifically, both the material of the active layer 224 and the material of the barrier layer 223 may use amorphous silicon, and the barrier layer 223 and the active layer 224 are non-contact connected, and the barrier layer 223 is used to further block the first metal trace 2211 from the second metal trace 2221 at the trace crossover area 10.

In an embodiment, as shown in FIG. 2 and FIG. 4, an insulating layer 225 covering the first metal layer 221 is disposed between the first metal layer 221 and the second metal layer 222, and the barrier layer 223 is disposed on a side of the insulating layer 225 close to the second metal layer 222. Specifically, the insulating layer 225 is disposed on a flexible substrate, the gate 2212, and the second metal trace 2221, and covers the gate electrode 2212 and the second metal trace 2221. The active layer 224 is disposed on the insulating layer 225, the second metal layer 222 is disposed on the insulating layer 225, and the source/drain electrodes 2222 are respectively connected to both ends of the active layer 224. It is understood that although an insulating layer 225 is provided between the first metal layer 221 and the second metal layer 222, a method of increasing the thickness of the metal traces is adopted to ensure a charging rate of a display panel in existing display panels of high refresh rate and high-resolution, which causes the thickness of the insulating layer 225 to be relatively less. Moreover, a distance between the first metal trace 2211 and the second metal trace 2221 is shorter, which reduces the insulation function of the insulating layer 225. Therefore, the use of the barrier layer 223 in the present application can further reduce the risk of a short circuit occurring between the first metal trace 2211 and the second metal trace 2221.

In one embodiment, thicknesses of the active layer 224 and the barrier layer 223 are the same. Obviously, when the thicknesses of the active layer 224 and the barrier layer 223 are the same and the active layer 224 and the barrier layer 223 are prepared by using the same support, there is no need to consider a thickness difference between the active layer 224 and the barrier layer 223, thereby reducing the complexity of the fabrication process of the active layer 224 and the barrier layer 223.

In one embodiment, as shown in FIG. 1 and FIG. 2, the first metal layer 221 comprises a plurality of first metal traces 2211, and the second metal layer 222 comprises a plurality of second metal traces 2221. The trace crossover area 10 comprises a plurality of trace crossover sub-areas 11, a projection of the multiple first metal traces 2211 on the substrate 21 and a projection of the plurality of second metal traces 2221 on the substrate 21 overlap at each of the trace crossover sub-areas 11, respectively;

The barrier layer 223 comprises a plurality of barrier sub-layers 2231 corresponding to the plurality of trace crossover sub-areas 11, and the barrier sub-layer 2231 at least covers the corresponding trace crossover sub-area 11.

It can be understood that the first metal layer 221 may comprise a plurality of first metal traces 2211, and the second metal layer 222 may comprise a plurality of second metal traces 2221. The trace crossover area 10 comprises a plurality of crossover sub-areas 11, and a projection of the plurality of first metal traces 2211 on the substrate 21 overlaps a projection of the plurality of the second metal traces 2221 on the substrate 21 in each of the crossover sub-areas 11. Obviously, the barrier layer 223 comprises a plurality of barrier sub-layers 2231 corresponding to the plurality of crossover sub-areas 11, respectively. The barrier sub-layer 2231 at least covers the corresponding trace crossover sub-area 11.

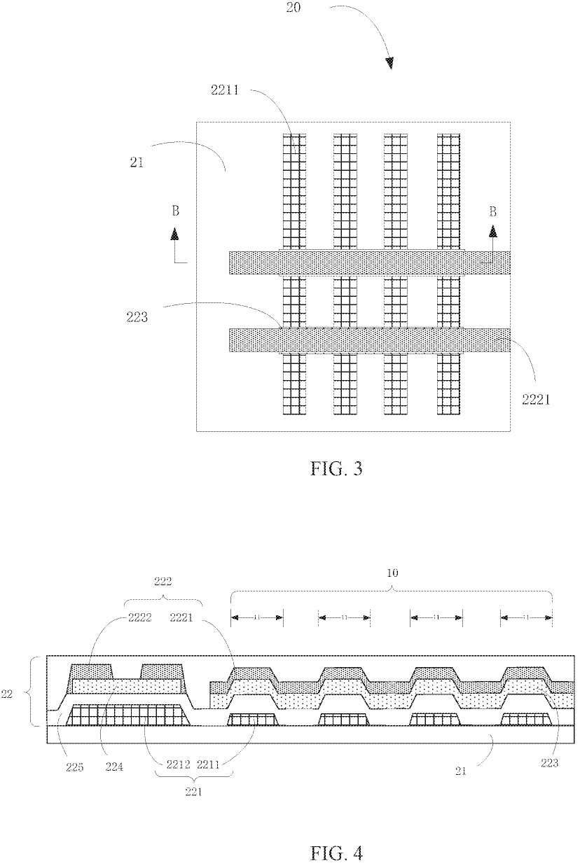

In one embodiment, as shown in FIG. 3 and FIG. 4, among the plurality of barrier sub-layers 2231, adjacent portions of the barrier sub-layer 2231 are connected as a whole, since adjacent portions of the barrier sub-layer 2231 are close to each other, so that the adjacent sub-layers 2231 may be connected as a whole and formed as a whole to reduce the complexity of the fabrication process of the barrier layer 223.

In one embodiment, a part of the barrier sub-layers 2231 that are integrated connected are arranged along an extension direction of one of the first metal traces or along an extension direction of one of the second metal traces 2221.

Specifically, a width of the barrier layer 223 at the trace crossover area 10 is greater than a width of the first metal trace 2211 at the trace crossover area 10. Of course, a width of the barrier layer 223 at the trace crossover area 10 is greater than a width of the second metal trace 2221 at the trace crossover area 10. Thus, the barrier layer 223 completely blocks the first metal trace 2211 or the second metal trace 2221 in the trace crossover area 10 and achieves a better short-circuit prevention effect.

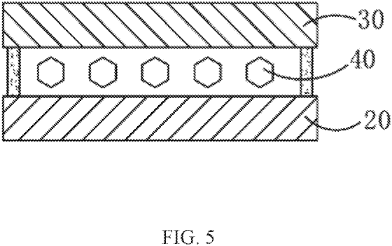

The present application also provides a display panel. As shown in FIG. 5, the display panel comprises a color filter substrate 30 and an array substrate 20 as described in the previous embodiment. A liquid crystal layer 40 is disposed between the color filter substrate 30 and the array substrate 20.

In summary, in the present application, the barrier layer 223 is disposed between the first metal layer 221 and the second metal layer 222, and the barrier layer 223 covers at least the trace crossover area 10, thereby preventing the first metal from being short-circuited with the second metal trace 2221 at the trace crossover area 10, which improves a stability of the first metal trace 2211 and the second metal trace 2221 at the trace crossover area 10.

The descriptions of the above embodiments are only used to help understand the technology of the present application, solutions and their core ideas; those of ordinary skill in the art should understand that they can still modify the technical solutions described in the foregoing embodiments or equivalently replace some of the technical features, and these modifications or replacements do not make the essence of the corresponding technical solutions deviate from the scope of the technical solutions of the embodiments of the present application.

What is claimed is:

1. An array substrate comprising a substrate and a thin film transistor layer disposed on the substrate, wherein:
the thin film transistor layer comprises a first metal layer and a second metal layer disposed above the first metal layer, the first metal layer comprises at least one first metal trace, the second metal layer comprises at least one second metal trace, the thin film transistor layer comprises a trace crossover area, and a projection of the first metal trace on the substrate overlaps a projection of the second metal trace on the substrate in the trace crossover area; and
a barrier layer is disposed between the first metal layer and the second metal layer, and the barrier layer at least covers the trace crossover area.

2. The array substrate according to claim 1, wherein the first metal layer further comprises a gate, the thin film transistor layer further comprises an active layer disposed over the gate, the second metal layer further comprises source/drain electrodes connected to both ends of the active layer, a material of the active layer is same as a material of the barrier layer, and the active layer and the barrier layer are an integrally formed structure.

3. The array substrate according to claim 2, wherein an insulating layer covering the first metal layer is disposed between the first metal layer and the second metal layer, and the barrier layer is provided on the insulating layer at a side close to the second metal layer.

4. The array substrate of claim 2, wherein thicknesses of the active layer and the barrier layer are same.

5. The array substrate according to claim 2, wherein the materials of the active layer and the barrier layer are both amorphous silicon.

6. The array substrate according to claim 1, wherein the first metal layer comprises a plurality of the first metal traces, the second metal layer comprises a plurality of the second metal traces, the trace crossover area comprises a plurality of crossover sub-areas, and projections of the plurality of first metal traces on the substrate overlap projections of the plurality of second metal traces on the substrate in each of the trace crossover sub-areas; and
the barrier layer comprises a plurality of barrier sub-layers corresponding to the plurality of trace crossover sub-areas, respectively, and the barrier sub-layers cover at least the corresponding trace crossover sub-areas.

7. The array substrate according to claim 6, wherein among the plurality of barrier sub-layers, adjacent barrier sub-layers are integrally connected.

8. The array substrate according to claim 7, wherein a part of the barrier sub-layers that are integrated connected is disposed along an extending direction of one of the first metal traces or along an extending direction of one of the second metal traces.

9. The array substrate of claim 1, wherein a width of the barrier layer at the trace crossover area is greater than a width of the first metal trace at the trace crossover area.

10. The array substrate of claim 1, wherein a width of the barrier layer at the trace crossover area is greater than a width of the second metal trace at the trace crossover area.

11. A display panel comprising a color filter substrate and the array substrate according to claim 1, wherein a liquid crystal layer is disposed between the color filter substrate and the array substrate.

12. The display panel according to claim 11, wherein the first metal layer further comprises a gate, the thin film transistor layer further comprises an active layer disposed over the gate, the second metal layer further comprises source/drain electrodes connected to both ends of the active layer, a material of the active layer is same as a material of the barrier layer, and the active layer and the barrier layer are an integrally formed structure.

13. The display panel according to claim 12, wherein an insulating layer covering the first metal layer is disposed between the first metal layer and the second metal layer, and the barrier layer is provided on the insulating layer at a side close to the second metal layer.

14. The display panel of claim 12, wherein thicknesses of the active layer and the barrier layer are same.

15. The display panel according to claim 12, wherein the materials of the active layer and the barrier layer are both amorphous silicon.

16. The display panel according to claim 11, wherein the first metal layer comprises a plurality of the first metal traces, the second metal layer comprises a plurality of the second metal traces, the trace crossover area comprises a plurality of crossover sub-areas, and projections of the plurality of first metal traces on the substrate overlap projections of the plurality of second metal traces on the substrate in each of the trace crossover sub-areas; and
the barrier layer comprises a plurality of barrier sub-layers corresponding to the plurality of trace crossover sub-areas, respectively, and the barrier sub-layers cover at least the corresponding trace crossover sub-areas.

17. The display panel according to claim 16, wherein among the plurality of barrier sub-layers, adjacent barrier sub-layers are integrally connected.

18. The display panel according to claim 17, wherein a part of the barrier sub-layers that are integrated connected is disposed along an extending direction of one of the first metal traces or along an extending direction of one of the second metal traces.

19. The display panel of claim 11, wherein a width of the barrier layer at the trace crossover area is greater than a width of the first metal trace at the trace crossover area.

20. The display panel of claim 11, wherein a width of the barrier layer at the trace crossover area is greater than a width of the second metal trace at the trace crossover area.
